(19) United States
(12) Patent Application Publication
(10) Pub. No.: US 2026/0351511 A1
(43) Pub. Date: Nov. 5, 2026

(54) SEMICONDUCTOR PROCESSING TOOL WITH IMPROVED PUMPING EFFICIENCY DURING WAFER TRANSFER AND METHODS OF USING SAME

(71) Applicant: Taiwan Semiconductor Manufacturing Company, LTD., Hsinchu (TW)

(72) Inventors: Huachun LIU, Hsinchu (TW); Shao-Ling CHANG, Hsinchu (TW); Fu-Ting SUNG, Yangmei (TW)

(21) Appl. No.: 19/198,020

(22) Filed: May 3, 2025

(51) Int. Cl. H01J 37/18; H01J 37/305; H10N 50/01

(52) U.S. Cl. CPC H01J 37/185; H01J 37/3056; H10N 50/01; H01J 2237/182; H01J 2237/186; H01J 2237/24585

(57) ABSTRACT

Ion beam etching of magnetic tunnel junction mesas, or other processing, is performed on a semiconductor wafer disposed in a process chamber. After the processing is complete, the wafer is transferred from the process chamber to a transfer module. Pressure in the transfer module is raised by flowing an inert gas into the transfer module. After raising the pressure in the transfer module, the wafer is transferred from the transfer module through a passthrough to a vacuum transfer module. During the transfer of the wafer through the passthrough, the inert gas flows through the passthrough via a showerhead of the passthrough and concurrent pumping of the passthrough. The concurrent pumping employs a turbomolecular pump or other high vacuum pump for at least an initial period of the flow of the inert gas through the passthrough.

### BACKGROUND

The following relates to the semiconductor processing and processing tool arts, semiconductor wafer transfer arts, ion beam etching arts, and related arts.

Fabrication of electronic devices and device structures such as magnetic tunnel junction (MTJ) devices and structures is sensitive to local defects. For example, a MTJ may comprise thin layers of a magnetic material such as CoFeB spaced apart by a barrier layer such as magnesium oxide (MgO). Residue deposited on MTJ mesas during the etch processing performed to isolate the MTJ mesas, or during wafer transfer after such etching, can cause shorting of some MTJ mesas, thereby reducing device yield. Measures taken to limit such contamination include using automated wafer handling and performing wafer processing and transfer under vacuum.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates an ion beam etching (IBE) system.

FIGS. 2 and 3 show cut C-C and bottom views, respectively, of one instance of a showerhead of the IBE system of FIG. 1, where cut C-C of FIG. 2 is indicated in FIG. 3.

FIG. 4 diagrammatically illustrates a partially exploded perspective view of the pass-through of the IBE system of FIG. 1.

FIG. 5 diagrammatically illustrates an ion beam etching process including wafer transfer after the etching, employing the IBE system of FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As previously noted, residue deposited on magnetic tunnel junction (MTJ) mesas during the etch processing performed to isolate the MTJ mesas, or during wafer transfer after such etching, can cause shorting of some MTJ mesas, thereby reducing device yield. In more general terms, residue deposited on electronic devices during processing in a process chamber, or during wafer transfer out of the process chamber after such processing, can damage the electronic devices thereby reducing device yield. Measures taken to limit such contamination include using automated wafer handling and performing wafer processing and transfer under vacuum.

These problems can be enhanced when the processing is performed at high or ultrahigh vacuum. For example, ion beam etching (IBE) is performed at lower pressure than some other types of semiconductor processing. In IBE or other processing performed in a processing chamber at high vacuum or ultrahigh vacuum, the pressure significantly during transfer of the wafer after the processing. In the example of IBE performed to etch MTJ mesas, the IBE chamber is pumped by a turbomolecular pump (i.e., turbo pump) or other high vacuum or ultrahigh vacuum pump (or plurality of pumps). The etching is performed at a pressure P_{IBE} in a range (in some nonlimiting illustrative examples) of about 0.01 mTorr to about 0.05 mTorr. After completion of the IBE processing, the turbomolecular pump continues to pump on the IBE chamber, and so the pressure in the chamber after the IBE processing begins to decrease toward the base pressure of the IBE chamber, which may be below about 10⁻⁶ Torr in some nonlimiting examples. On the other hand, the vacuum transfer module that interfaces with the load port may be at a relatively much higher pressure, e.g., in a range of about 20 mTorr to 100 mTorr in some nonlimiting examples. Wafer removal from the IBE chamber thus involves the wafer being exposed to increasingly higher pressure as it moves from the IBE chamber to the vacuum transfer module. This takes time, and presents substantial opportunity for post etchant residues to deposit on the wafer.

In embodiments disclosed herein, improved approaches are disclosed, which leverage a combination of adjustable flow of inert gas and rapid pumping utilizing the turbomolecular pump to advantageously enable more rapid wafer transfer with reduced opportunity for post etch residue deposition onto the semiconductor wafer.

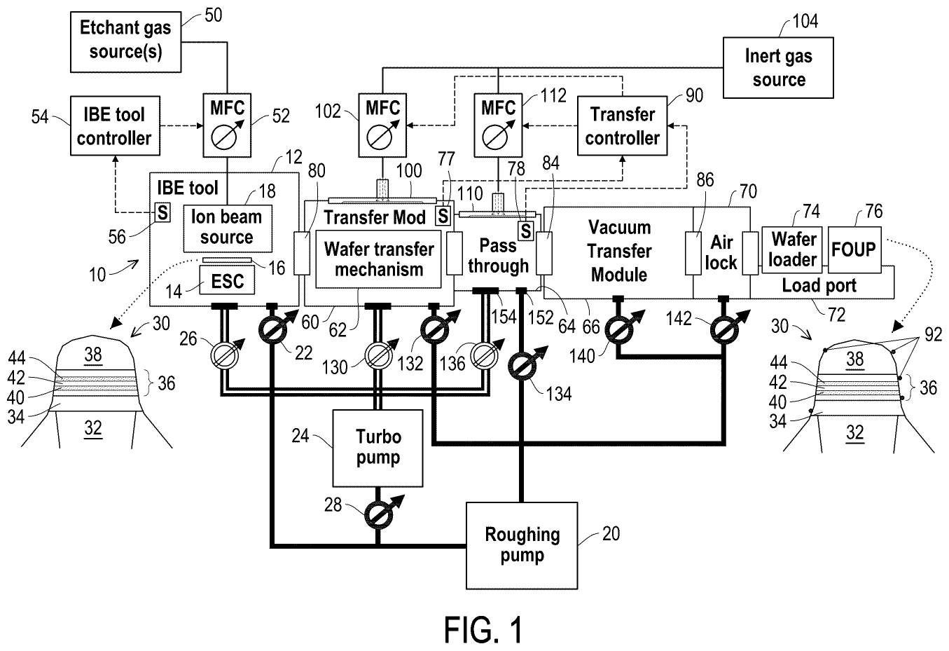

With reference to FIG. 1, an ion beam etching (IBE) system is diagrammatically illustrated. The IBE system includes an IBE tool 10 which includes a process chamber 12, a wafer holder 14 configured to hold a semiconductor wafer 16, and an ion beam source 18 arranged to direct an ion beam toward the wafer holder 14 (and, hence, toward the semiconductor wafer 16 which is held by the wafer holder 14). The IBE tool 10 may be variously configured, such as to perform reactive ion beam etching using reactive gases, ion beam milling, or so forth. The process chamber 12 is a high vacuum chamber or ultrahigh vacuum chamber, which is connected to a roughing pump 20 via a valved connection 22, and which is connected to a turbomolecular pump (i.e., turbo pump) 24 via a high (or ultrahigh) vacuum valved connection 26. In the nonlimiting illustrative example of FIG. 1, the roughing pump 20 is also connected to back the turbo pump 24 by way of a valved connection 28; however, it is alternatively contemplated to provide a separate backing pump for the turbomolecular pump 24. Rough pumping refers to pumping capable of attaining a minimum vacuum pressure of about 1 mTorr (e.g., about 0.1 mTorr or higher). The roughing pump 20 is a pump for performing rough pumping, and may for example comprise a mechanical pump or a dry pump such as a scroll pump, diaphragm pump, screw rotor pump, sorption pump, a combination thereof, or so forth. In some examples described herein the roughing pump 20 is a dry pump which is advantageous for semiconductor processing to avoid potentially contaminating the semiconductor wafer 16 with oil.

High vacuum pumping refers to pumping capable of attaining a minimum vacuum pressure of below about 1 mTorr (e.g., below about 0.1 mTorr in some embodiments, and more typically in the 10⁻⁵ Torr range or 10⁻⁶ Torr range or lower. In the illustrative examples herein, the turbomolecular pump (i.e., turbo pump) 24 is employed for the high vacuum pumping; however, other types of high vacuum (or ultra-high vacuum) pumps can be used, such as an oil diffusion pump, an ion pump, a cryogenic pump, a combination thereof, or so forth. In some embodiments, an oil-free high vacuum pump such as the illustrative turbomolecular pump 24 is advantageously employed to avoid potentially contaminating the semiconductor wafer with oil. As used herein, ultrahigh vacuum pumping is considered to be a type of high vacuum pumping, which is capable of attaining a lower minimum vacuum pressure, e.g., below about 10⁻⁸ Torr in some nonlimiting examples of ultrahigh vacuum pumping.

In use, with the process chamber 12 of the IBE tool 10 initial at atmospheric pressure, the valve 22 is open (and valve 26 is closed) so that the roughing pump 20 pulls vacuum to a crossover pressure, e.g., in a range of about 1 mTorr as a nonlimiting example. When the crossover pressure is attained, the valve 22 is closed and the valve 26 is opened (not necessarily simultaneously) so that the turbomolecular pump 24 is now pulling vacuum to further lower the pressure in the process chamber 12, e.g., down to a base pressure of about 10⁻⁶ Torr in some nonlimiting examples. During operation of the turbomolecular pump 24, the roughing pump 20 provide backing for the turbomolecular pump 24 via an open valve 28. Note that such pump-down from atmospheric pressure is not performed after each wafer run, but only after maintenance of the IBE tool 10 or other occasion for which the process chamber 12 is brought up to atmospheric pressure.

To perform etch processing performed to isolate the MTJ mesas, the semiconductor wafer 16 is loaded onto the wafer holder 14. In the illustrative example, the wafer holder 14 is an electrostatic (ESC) wafer holder, but other types of wafer holder are contemplated. In this application of the IBE tool 10, the semiconductor wafer 16 includes a magnetic tunnel junction (MTJ) multilayer structure, and the ion beam etching on the semiconductor wafer 16 disposed in the process chamber 12 includes performing patterned etching of the MTJ multilayer structure to form MTJ mesas 30. FIG. 1 diagrammatically shows a cut view of one illustrative MTJ mesa 30. In this nonlimiting illustrative example, the MTJ mesa 30 includes a bottom electrode via (BEVA) 32, a bottom electrode (BE) 34 which in this example comprises titanium nitride (TiN), a magnetic tunnel junction (MTJ) 36, and a top electrode (TE) 38 which in this example comprises TiN. The MTJ 36 may, in one nonlimiting example, include a tunnel junction stack including a pinning layer 40, a barrier layer 42, and a free layer 44. In one more specific nonlimiting example, the pinning layer 40 may comprise CoFeB, the barrier layer 42 may comprise MgO, and the free layer 44 may comprise CoFeB. These are merely some nonlimiting illustrative examples. It will also be appreciated that while FIG. 1 diagrammatically shows a cut view of a single representative MTJ mesa 30, the ion beam etching is patterned etching of the MTJ multilayer structure to form (or isolate) a two dimensional array of MTJ mesas 30.

To perform the IBE processing, the IBE tool 10 further includes (or, is operatively connected with) an etchant gas source or sources 50 which flow gas through a mass flow controller (MFC) 52 to the ion beam source 18. (Optionally, the etchant gas source or sources 50 may also include a carrier gas, e.g., an inert gas such as argon). The ion beam source 18 is not shown in detail in FIG. 1, but may by way of a nonlimiting example include anode and cathode electrodes, and an accelerating electrode (or grid). In operation, the anode and cathode apply an electric field to the gas entering the ion beam source 18 to produce a plasma, and the accelerating electrode (or grid) accelerates ions of the plasma toward the semiconductor wafer 16 disposed on the wafer holder 14. Focusing coils may be provided to shape and/or direct the ion beam toward the semiconductor wafer 16. The ions of the ion beam etch the semiconductor wafer 16. To perform patterned etching, e.g., to form an array of MTJ mesas 30, the regions that are etched may be controlled by a patterned photoresist disposed on the semiconductor wafer 16 which was previously patterned by photolithography, nano imprint lithography, or the like. In the case of forming (or isolating) MTJ mesas 30, the semiconductor wafer 16 suitably includes an MTJ multilayer structure that is etched by the IBE processing. As further diagrammatically shown in FIG. 1, an IBE tool controller 54 (e.g., implemented by a microprocessor or microcontroller and suitable ancillary electronics such as random access memory and so forth) controls the mass flow controller 52 to supply a controlled flow rate of the etchant gas 50 to the ion beam source 18, optionally based on feedback provided by a sensor 56, such as a pressure sensor that monitors pressure inside the processing chamber 12. Like the MFC 52, the IBE tool controller 54 and/or sensor 56 may be considered part of the IBE tool 10, or alternatively may be considered to be operatively connected with the IBE tool 10.

With continuing reference to FIG. 1, the IBE system further includes a wafer transfer path for transferring out the semiconductor wafer 16 after IBE processing. The illustrative wafer transfer path includes a transfer module 60 with an automatic wafer transfer mechanism 62, and a passthrough 64 connecting the transfer module 60 and a vacuum transfer module 66. The illustrative transfer module 60 is an external transfer module that is connected with the IBE tool 12 (and more particularly with the processing chamber 12) by mating vacuum flanges or the like. However, it is alternatively contemplated for the transfer module to be integral with the IBE tool 10. The wafer transfer mechanism 62 may, by way of some nonlimiting examples, comprise a robot with edge contact grippers or a platen for holding the semiconductor wafer, and/or a linear motor actuator, linear slide, conveyor belt, et cetera.

The illustrative vacuum transfer module 66 is connected with an air lock 70 for transferring the semiconductor wafer to a load port 72. In the illustrative example, the load port 70 includes a wafer loader 74 for automatically transferring the semiconductor wafer to an illustrative front opening unified pod (FOUP) 76 or another type of wafer carrier. The wafer loader 74 may, by way of some nonlimiting examples, comprise an articulated-arm robot with edge contact grippers or platen, linear motor actuator, linear slide, conveyor belt, et cetera.

In the illustrative example, the vacuum transfer module 66 provides interfacing with the load port 72. However, it is contemplated for the vacuum transfer module 66 to provide additional and/or other types of interfacing. For example, in a semiconductor tool cluster, the vacuum transfer module could provide interfacing between the IBE tool 10 and another tool or tools of the semiconductor tool cluster. Such a tool cluster can advantageously perform a sequence of two or more processes by respective two or more tools without the semiconductor wafer being exposed to atmosphere.

The transfer module 60, passthrough 64, and vacuum transfer module 66 are vacuum chambers, since they are connected with the roughing pump 20 and (in some cases) with the turbo pump 24 to draw vacuum within the respective modules 60 and 66 and passthrough 64. Hence, these may sometimes be referred to herein as vacuum chambers 60, 64, and 66, or more briefly as chambers 60, 64, and 66. In general, the operating pressure increases along the semiconductor wafer transfer path from the processing chamber 12 of the IBE tool 10, whose base pressure may be below about 10⁻⁶ Torr in some nonlimiting examples, to the transfer module 60 which may have a pressure of below about 0.1 mTorr in some nonlimiting examples, to the passthrough 64 which may have a pressure of about 1-10 mTorr in some nonlimiting examples, to the vacuum transfer module 66 which may have a pressure of about 20-100 mTorr in some nonlimiting examples. Pressures may be measured by pressure sensors, e.g., by an illustrative pressure sensor 77 disposed in the transfer module 60 to monitor pressure in the transfer module 60, and an illustrative pressure sensor 78 disposed in the passthrough 64 to monitor pressure in the passthrough 64. These are merely illustrative examples, and additional and/or other pressure sensors may be included to monitor pressures during the wafer transfer, e.g., in the vacuum transfer module 66 (not shown).

To enable maintaining the different vacuum chambers 60, 64, 66 at different pressures, gate valves may be provided. For example, a gate valve 80 connects (or said otherwise, is interposed between) the processing chamber 12 of the IBE tool 10 and the transfer module 60 (in the case where this is an external transfer module), a gate valve 82 connects (or said otherwise, is interposed between) the transfer module 60 and the passthrough 64, and a gate valve 84 connects (or said otherwise, is interposed between) the passthrough 64 and the vacuum transfer module 66. A further gate valve 86 connects the vacuum transfer module 66 and the air lock 70. By gate valve, it is meant that these valves 80, 82, and 84 have sufficiently large orifices (when open) for the semiconductor wafer 16 to pass therethrough. The various gate valves 80, 82, 84, and 86 may have automated actuators and be controlled by a transfer controller 90 (e.g., implemented by a microprocessor or microcontroller and suitable ancillary electronics such as random access memory and so forth).

During wafer transfer from one chamber to an adjacent chamber, the gate valve between the chambers is opened to allow the semiconductor wafer 16 to pass. More particularly, transferring the semiconductor wafer 16 from the processing chamber 12 of the IBE tool 10 to the transfer module 60 entails opening the gate valve 80. Transferring the semiconductor wafer 16 from the transfer module 60 to the passthrough 64 entails opening the gate valve 82. Transferring the semiconductor wafer 16 from the passthrough 64 to the vacuum transfer module 66 entails opening the gate valve 84. In each case, before opening the gate valve, the pressures in chambers connected by the gate valve should be approximately equalized. This can be done by operating the roughing pump 20 and/or the turbo pump 24 to evacuate the upcoming chamber along the transfer path to a pressure low enough to enable the gate valve between the chambers to open, and/or by increasing pressure in the chamber currently holding the semiconductor wafer 16 to bring it up to about the pressure of the upcoming chamber.

A large pressure difference when the gate valve is opening can result in gas flow, e.g., from the higher-pressure chamber into the lower-pressure chamber, as the pressures in the two chambers that are connected by the open gate valve equalize. The gas flow may be turbulent, and/or may dislodge post-etchant residue particles, which can then land on the surface of the semiconductor wafer 16. This post-etchant residue landing on the wafer surface can be difficult or impossible to remove by subsequent wafer cleaning, and can disadvantageously decrease device yield. In the illustrative application of IBE etching to isolate MTJ mesas, such post-etchant residue dislodged and deposited on the wafer surface during the wafer transfer can cause shorting of some MTJ mesas, thereby reducing MTJ device yield. This is diagrammatically shown on the right side of FIG. 1, by way of illustration of the cut view of the representative MTJ mesa 30, which on the right side now includes post-etchant residue particles 92 that have been dislodged and deposited on the wafer surface (and more particularly on the MTJ mesa 30) during the wafer transfer. In particular, particles 92 that land on edges of the MTJ layers 40, 42, 44 at the sidewall of the MTJ mesa 30 can frequently short the magnetic tunnel junction of the MTJ mesa 30.

The IBE system of FIG. 1 includes features that advantageously reduce post-etchant residue contamination of the MTJ mesas (or, more generally, devices and/or other critical structures formed on the surface of the semiconductor wafer 16). These features provide improved pumping efficiency and hence lower pressure which reduces post-etchant residue 92. These features also provide flow of an inert gas over the surface of the semiconductor wafer 16, which also helps protect the surface of the semiconductor wafer 16 from post-etchant residue 92.

One such feature comprises a showerhead 100 of the transfer module 60, which is connected with a MFC 102 to flow inert gas from an inert gas source 104 through the transfer module 60. This gas flow system 100, 102 provides for rapidly increasing the pressure in the transfer module 60 to bring it up to about the pressure in the passthrough 64 before opening the gate valve 82 between the chambers 60 and 64. Likewise, the passthrough 64 includes a showerhead 110, which is connected with a MFC 112 to flow inert gas from the inert gas source 104 through the passthrough 64.

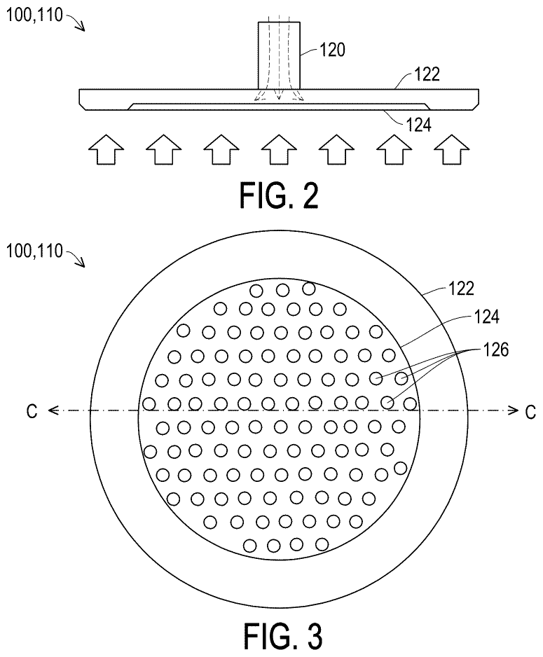

FIGS. 2 and 3 show cut C-C and bottom views, respectively, of one instance of a showerhead of the IBE system of FIG. 1 (i.e., showerhead 100 or showerhead 110), where cut C-C of FIG. 2 is indicated in FIG. 3 and the viewing direction for the bottom view of FIG. 3 is indicated by upward-directed block arrows in FIG. 2. The showerhead 100 or 110 includes an inlet 120 feeding into a plate 122 with an orifice 124 comprising an array of openings 126. Hence, the showerhead 100 or 110 distributes the inert gas flowing into the inlet 120 approximately uniformly through the array of openings 126. The illustrative array of openings 126 has a hexagonal pattern, but other patterns of openings, or uniform randomly distributed openings, can be employed.

With reference back to FIG. 1, the showerhead 100 thus uniformly flows the inert gas along a generally downward flow path through the transfer module 60, with the (mass) flow rate controlled by the MFC 102. Likewise, the showerhead 110 uniformly flows the inert gas along a generally downward flow path through the passthrough 64, with the (mass) flow rate controlled by the MFC 112. These flows advantageously enable controlled, and potentially rapid, pressurization of the respective chamber 60 or 64. Additionally, as the flow is generally downward, it impinges on the surface of the semiconductor wafer 16 and can act to prevent any dislodged post-etchant residue particles from contaminating the surface of the semiconductor wafer 16 and, e.g., landing as particulates 92 on MTJ mesas 30. The inert gas sourced by the inert gas source 104 may, for example, be argon or another noble gas, or may be nitrogen, or a mixture of two or more such gases, by way of some nonlimiting illustrative examples.

Along with the showerhead 100 and its MFC 102, the transfer module is also connected with both the roughing pump 20 and the turbo pump 24. In illustrative FIG. 1, a valve 130 controls operative connection of the roughing pump 20 with the transfer module 60, and a valve 132 controls operative connection of the turbo pump 24 with the transfer module 60. A valve 134 controls operative connection of the roughing pump 20 with the passthrough 64, and a valve 136 controls operative connection of the turbo pump 24 with the passthrough 64. Additionally, a valve 140 controls operative connection of the roughing pump 20 with the vacuum transfer module 66, and a valve 142 controls operative connection of the roughing pump 20 with the air lock 70. As the vacuum transfer module 66 and airlock 70 are not evacuated to pressure below about 1-10 mTorr, in the illustrative embodiment there is no high vacuum connection of the turbo pump 24 to the vacuum transfer module 66 or airlock 70.

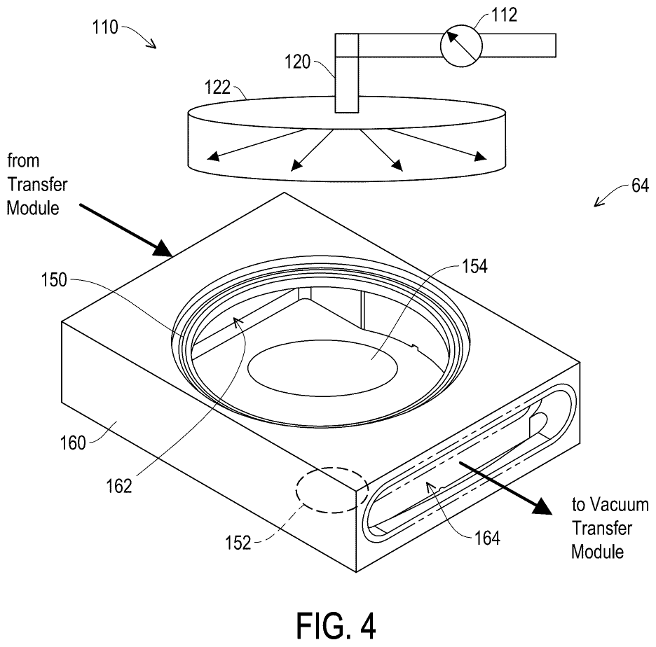

With reference to FIG. 4, a nonlimiting illustrative example of one suitable embodiment of the passthrough 64 is shown. FIG. 4 shows a partially exploded perspective view of the passthrough 64, in which the showerhead 110 is shown detached from a receptacle 150 in a top of the passthrough 64 into which the plate 122 of the showerhead 110 mounts. The passthrough 64 includes a rough pumping port 152 and a high vacuum port 154. As diagrammatically shown in FIG. 1, the rough pumping port 152 is connected with the valve 134 that controls operative connection of the roughing pump 20 with the passthrough 64, and the high vacuum pumping port 154 is connected with the valve 136 that controls operative connection of the turbo pump 24 with the passthrough 64. As further seen in FIG. 4, the passthrough comprises a hollow transfer tube 160 including a first end 162 configured (e.g., by a vacuum flange) to connect with the semiconductor processing tool or a transfer module 60 thereof (e.g., via the gate valve 82), and a second end 164 configured (e.g., by a vacuum flange) to connect with the vacuum transfer module 66 (e.g., via the gate valve 84). The hollow transfer tube 160 further has the vacuum port 154 configured (e.g., by a suitable vacuum line coupler) to connect with a high vacuum line. The hollow transfer tube 160 has an open interior volume or passthrough path extending between an orifice at the first end 162 connecting with the gate valve 82 and an orifice at the second end 164 connecting with the gate valve 84. The vacuum ports 152 and 154 are disposed on an opposite side of the hollow transfer tube from the showerhead 110.

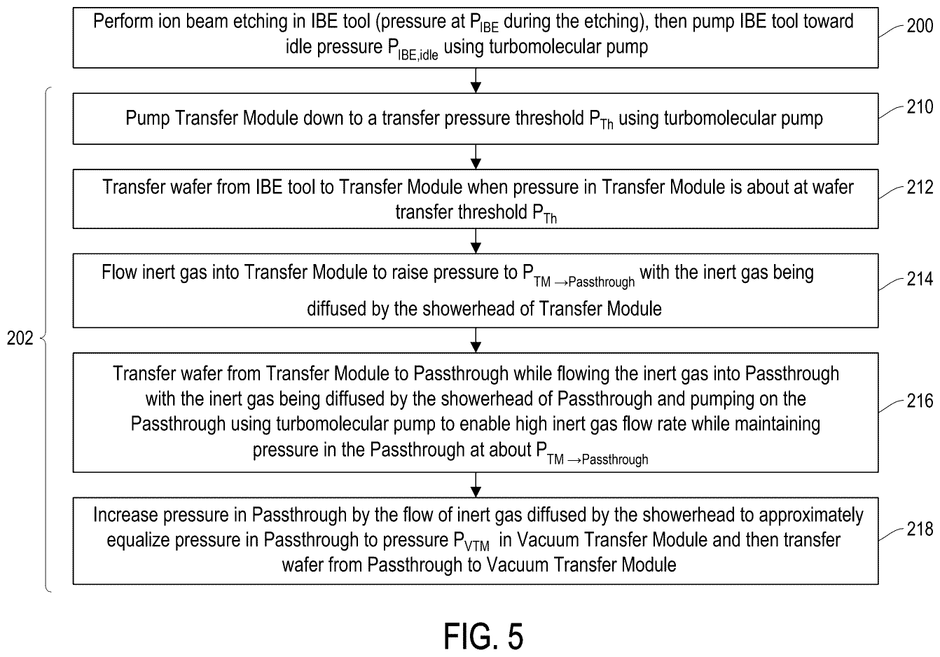

With reference back to FIG. 1 and with further reference to FIG. 5, a method for performing IBE etching of the semiconductor wafer 16 and subsequent transfer of the semiconductor wafer through the wafer transfer path 60, 64, 66 is described. FIG. 5 diagrammatically illustrates an ion beam etching process including wafer transfer after the etching, employing the IBE system of FIG. 1. In an operation 200, ion beam etching of the semiconductor wafer 16 is performed in the IBE tool 10. During the IBE processing, the pressure in the processing chamber 12 is at an elevated pressure denoted herein as P_{IBE}, due to flow of the etchant gas(es) into the ion beam source 18 within the processing chamber 12 via the MFC 52. The IBE processing is performed with suitable etchant gas(es) for etching the materials to be removed, e.g., the TiN, MgO, and CoFeB layers of a MTJ multilayer structure to isolate the illustrative MTJ mesas 30. Optionally, the input gas(es) may also include an inert carrier gas. The MTJ multilayer structure on the semiconductor wafer 16 may also include a patterned photoresist to protect the areas of the MTJ mesas 30 from the ion beam etching. After the IBE etching is completed, the flow of the etchant gas(es) and optional carrier gas is reduced or valved off entirely, and the turbo pump 24 continues to pump on the processing chamber 12 via the open valve 26 to pump (the processing chamber 12 of) the IBE tool 10 toward its idle pressure, denoted here as P_{IBE,idle}. In some nonlimiting examples that may be suitable for MTJ mesa etching, the pressure P_{IBE} in the processing chamber 12 during the etching may be in a range of about 0.01-0.05 mTorr, and after the etching is completed the pressure begins to decrease toward the idle pressure P_{IBE,idle} which may be below about 10⁻⁶ Torr. The ion beam etch processing operation 200 is suitably controlled by the IBE tool controller 54, which controls the MFC 52 to supply controlled flow of the etchant gas 50 to the ion beam source 18, optionally based on feedback provided by the pressure sensor 56 and/or other process monitoring sensors disposed within the processing chamber 12.

After the IBE processing is complete, in a process 202 the semiconductor wafer 16 is transferred along the semiconductor wafer transfer path 60, 64, 66 from the IBE tool 10 to the vacuum transfer module 66. The wafer transfer process 202 is controlled by a transfer controller 90, which has operative connections with the various gate valves 80, 82, 84, and 86, pressure sensors 77 and 78, and is also connected to control the MFC 102 to deliver controlled flow of the inert gas 104 through the showerhead 100 into the transfer module 60, and is connected to control the MFC 112 to deliver controlled flow of the inert gas 104 through the showerhead 110 into the passthrough 64. The transfer controller 90 may have other operative connections (not shown), such as to control actuators of the various high vacuum valves 130, 136 and rough vacuum valves 132, 134, 140, 142 to control pumping on the various vacuum chambers 60, 64, 66 during the wafer transfer process. Although the IBE tool controller 54 and the transfer controller 90 are diagrammatically shown in FIG. 1 as separate elements, it is contemplated for a single controller (e.g., implemented by a microprocessor or microcontroller and suitable ancillary electronics such as random access memory and so forth) to implement the functionality of both the IBE tool controller 54 and the transfer controller 90.

With continuing reference to FIGS. 1 and 5, the wafer transfer process 202 for removing the semiconductor wafer 16 from the IBE tool 10 to the vacuum transfer module 66 commences with an initial operation 210 in which the transfer module 60 is pumped down to a transfer pressure threshold P_{Th} using turbomolecular pump 24. In some nonlimiting examples, the transfer pressure threshold P_{Th} for opening the gate valve 80 to transfer the semiconductor wafer 16 from (the processing chamber 12 of) the IBE tool 10 to the transfer module 60 is a pressure that is at or below about 0.1 mTorr. The pressure sensor 77 in the transfer module 60 monitors the pressure in the transfer module 60 during this process. In an operation 212, once the transfer pressure threshold P_{Th} is achieved in the transfer module 60, the gate valve 80 is opened and the wafer is transferred from (the processing chamber 12 of) the IBE tool 10 to the transfer module 60, e.g., using the wafer transfer mechanism 62. The semiconductor wafer 16 is at this point in the transfer process located in the transfer module 60, which is sealed by both gate valves 80 and 82 being closed.

The next stage of the transfer process 202 is to move the wafer into the passthrough 64. To this end, in an operation 214 the inert gas 104 is flowed into the transfer module 60 (which initially is at or below the transfer pressure threshold P_{Th} for the previous step, e.g., below about 0.1 mTorr in some examples) to raise the pressure in the transfer module 60 to a higher pressure, denoted herein as threshold pressure P_{TM→Passthrough} for initiating transfer from the transfer module 60 to the passthrough 64. Again, the pressure sensor 77 in the transfer module 60 monitors the pressure in the transfer module 60 during this process. In the operation 214, the inert gas 104 is diffused into the transfer module 60 by the showerhead 100, and is thereby distributed as a generally downward flow over the upper surface of the semiconductor wafer 16. While flowing the inert gas into the transfer module 60 via the showerhead 100, simultaneously the turbo pump 24 and/or roughing pump 20 are operating, so as to create a continuous flow of the inert gas though the transfer module 60. The transfer controller 90 suitably controls the MFC 102 to control the flow rate of the inert gas in this pressurizing process. In some nonlimiting examples, the threshold pressure P_{TM→Passthrough} may be in a range of about 1-10 mTorr. Advantageously, the combination of controlled inflow of the inert gas 104 via the MFC 102 and showerhead 100 and concurrent pumping by the turbo pump 24 provides a controlled and generally downward flow of the inert gas, which reduces likelihood of dislodged post-etch residue landing on the surface of the semiconductor wafer 16 as particles 92. An additional advantage is that the positive flow of the inert gas 104 enables the pressure in the transfer module 60 to be brought up to the threshold pressure P_{TM→Passthrough} for initiating transfer from the transfer module 60 to the passthrough 64 relatively quickly. Hence, the residency time of the semiconductor wafer 16 in the transfer module 60 is reduced, again reducing the likelihood (and hence count) of particles 92 landing on the surface of the semiconductor wafer 16.

In an operation 216, when the threshold pressure P_{TM→Passthrough} is achieved in the transfer module 60, the semiconductor wafer 16 is transferred from the transfer module 60 to the passthrough 64. While this transfer is occurring, the inert gas 104 is advantageously flowed into the passthrough 64, with the inert gas being diffused by the showerhead 110 of the passthrough 64, and while concurrently pumping on the passthrough 64 using turbomolecular pump to enable a high flow rate of inert gas. Notably, the roughing pump 20 generally cannot provide effective concurrent pumping, because the roughing pump 20 typically does not provide efficient (or, in some instances, any) pumping of a vacuum chamber at a pressure of below about 1 mTorr. In one control approach suitably implemented by the transfer controller 90, the MFC 112 is set to the maximum flow of argon gas for which the pumping by the turbo molecular pump 24 (via the high vacuum port 154 and open valve 136) can maintain the pressure in the passthrough 64 (as monitored by the pressure sensor 78 in the passthrough 64) below a chosen pressure.

In a last operation 218 of the illustrative transfer process 202, pressure in the passthrough 64 is increased by the flow of inert gas 104 diffused by the showerhead 110 of the passthrough 64 to approximately equalize pressure in the passthrough 64 to a pressure P_{VTM} in the vacuum transfer module 66, at which point the gate valve 84 can be opened and the wafer transfer completed by moving the semiconductor wafer from the passthrough 64 to the vacuum transfer module 66. Again, the provision of the showerhead 110 and connected MFC 112, along with the high vacuum port 154 connected with the turbo pump 24 via the high vacuum valve 136, enables maintaining a high flow rate of the inert gas.

In some nonlimiting examples, the pressure P_{VTM} in the vacuum transfer module 66 may be in a range of about 20-100 mTorr. As this pressure P_{VTM} may be close to or above the maximum operating pressure of the turbo pump 24, the operation 218 may include a crossover step. For example, as the gradually increasing pressure in the passthrough 64 reaches a crossover pressure (which is safely below the maximum operating pressure of the turbo pump 24), the high vacuum valve 136 is closed and the roughing valve 134 is opened to switch the passthrough 64 from being pumped by the turbo pump 24 to being pumped by the roughing pump 20, which can then continue to provide pumping over the final portion of the pressure increase to P_{VTM}. Advantageously, the combination of diffused flow of argon via the showerhead 110 of the passthrough 64 and pumping (at least up to the crossover pressure) by the turbo pump 24 enables the argon flow through the passthrough 64 to be maximized. Moreover, the turbo pump 24 may be a higher volume pump than the roughing pump 20, e.g., as a nonlimiting illustrative example the turbo pump 24 may have a maximum pumping volume of 3600 L/s while the roughing pump may have a maximum pumping volume of 330 L/s. Hence, pumping with the turbo pump 24 via the high vacuum port 154 of the passthrough 64 during at least the initial portion of the operation 218 can be advantageous. In sum, the approach described, employing the showerhead 110 and concurrent high vacuum pumping advantageously reduces the residency time of the semiconductor wafer 16 in the passthrough 64 before it can be transferred to the vacuum transfer module 66, again reducing the likelihood (and hence count) of particles 92 landing on the surface of the semiconductor wafer 16. Additionally, the diffusion of the argon gas provided by the showerhead 110 of the passthrough 64 advantageously provides a generally downward flow of relatively high-flow-rate argon over the surface of the semiconductor wafer 16, further reducing particle landing events.

The method for performing IBE etching of the semiconductor wafer 16 and subsequent transfer of the semiconductor wafer through the wafer transfer path 60, 64, 66 described with reference to FIG. 5 is a nonlimiting illustrative example, and numerous variations are contemplated. For example, in the example of FIGS. 1 and 5, a single wafer transfer mechanism 62 disposed in the transfer module 60 moves the wafer from the transfer module 60 through the passthrough 64 to the vacuum transfer module 66. This approach entails having both gate valves 82 and 84 open for the second portion of that transfer (i.e., when moving the wafer from the passthrough 64 to the vacuum transfer module 66).

In a variant approach, a second wafer transfer mechanism may be provided in the vacuum transfer module. In this case, only the gate valve 82 may be open, to move the wafer into the passthrough and deposit it there (e.g., on a temporary wafer support in the passthrough). Thereafter, the gate valve 82 can be closed, and the MFC 112 and showerhead 110 used in combination with high vacuum pumping by the turbo pump 24 via the high vacuum port 154 to maintain diffuse and high volume flow of argon through the passthrough 64 to rapidly increase pressure in the passthrough 64 to the pressure P_{VTM} in the vacuum transfer module. At that point, the gate valve 84 can be opened (while keeping the gate valve 82 closed) and the second wafer transfer mechanism in the vacuum transfer module used to move the wafer from the passthrough into the vacuum transfer module.

In the following, some further embodiments are described.

In a nonlimiting illustrative embodiment, a semiconductor processing method includes: performing processing on a semiconductor wafer disposed in a process chamber; after the processing is complete, transferring the semiconductor wafer from the process chamber to a transfer module; raising pressure in the transfer module by flowing an inert gas into the transfer module; and, after raising the pressure in the transfer module, transferring the semiconductor wafer from the transfer module through a passthrough to a vacuum transfer module. During the transfer of the semiconductor wafer through the passthrough, the inert gas flows into the passthrough via a showerhead of the passthrough.

In a nonlimiting illustrative embodiment, a semiconductor processing system is disclosed. An ion beam etching (IBE) tool includes a process chamber, a wafer holder configured to hold a semiconductor wafer, and an ion beam source arranged to direct an ion beam toward the wafer holder. The semiconductor processing system further includes a vacuum transfer module, a load port configured to transfer semiconductor wafers to and from the vacuum transfer module, a transfer module connected with the IBE tool, a passthrough connecting the transfer module and the vacuum transfer module, and a wafer transfer mechanism configured to transfer semiconductor wafers between the IBE tool and the vacuum transfer module. A turbomolecular pump has a first valved vacuum connection to the transfer module via which the turbomolecular pump draws vacuum in the transfer module, and a second valved vacuum connection to the passthrough via which the turbomolecular pump draws vacuum in the passthrough.

In a nonlimiting illustrative embodiment, a passthrough for connecting a semiconductor processing tool with a vacuum transfer module includes a hollow transfer tube and a showerhead. The hollow transfer tube has a first end configured to connect with the semiconductor processing tool or a transfer module thereof, a second end configured to connect with the vacuum transfer module. The hollow transfer tube further has a vacuum port configured to connect with a high vacuum line. The showerhead is connected with the hollow transfer tube between the first end and the second end.

In a nonlimiting illustrative embodiment, ion beam etching of magnetic tunnel junction mesas, or other processing, is performed on a semiconductor wafer disposed in a process chamber. After the processing is complete, the wafer is transferred from the process chamber to a transfer module. Pressure in the transfer module is raised by flowing an inert gas into the transfer module. After raising the pressure in the transfer module, the wafer is transferred from the transfer module through a passthrough to a vacuum transfer module. During the transfer of the wafer through the passthrough, the inert gas flows through the passthrough via a showerhead of the passthrough and concurrent pumping of the passthrough. The concurrent pumping employs a turbomolecular pump or other high vacuum pump for at least an initial period of the flow of the inert gas through the passthrough.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor processing method comprising:
performing processing on a semiconductor wafer disposed in a process chamber;
after the processing is complete, transferring the semiconductor wafer from the process chamber to a transfer module;
raising pressure in the transfer module by flowing an inert gas into the transfer module;
after raising the pressure in the transfer module, transferring the semiconductor wafer from the transfer module through a passthrough to a vacuum transfer module; and
during the transfer of the semiconductor wafer through the passthrough, flowing the inert gas into the passthrough via a showerhead of the passthrough.

2. The semiconductor processing method of claim 1, wherein the transferring of the semiconductor wafer from the transfer module through the passthrough to the vacuum transfer module includes:
first transferring the semiconductor wafer from the transfer module to the passthrough; and
second transferring the semiconductor wafer from the passthrough to the vacuum transfer module;
wherein the first transferring includes concurrently flowing the inert gas into the passthrough via the showerhead of the passthrough and pumping the inert gas from the passthrough using a high vacuum pump.

3. The semiconductor processing method of claim 2, wherein the high vacuum pump comprises a turbomolecular pump.

4. The semiconductor processing method of claim 2, wherein the first transferring further includes:
sensing pressure in the passthrough using a pressure sensor; and
controlling the flow of the inert gas into the passthrough via the showerhead of the passthrough based on the sensed pressure in the passthrough.

5. The semiconductor processing method of claim 4, wherein the controlling of the flow of the inert gas into the passthrough includes:
controlling the flow of the inert gas into the passthrough via the showerhead of the passthrough to keep the sensed pressure in the passthrough at or below a threshold pressure.

6. The semiconductor processing method of claim 2, wherein the second transferring includes:
stopping the pumping of the inert gas from the passthrough using the high vacuum pump; and
opening a gate valve between the passthrough and the vacuum transfer module when the sensed pressure in the passthrough increases to a second threshold pressure.

7. The semiconductor processing method of claim 6, wherein the second transferring further includes:
pumping the inert gas from the passthrough using a roughing pump.

8. The semiconductor processing method of claim 1, wherein the flowing of the inert gas into the transfer module includes:
flowing the inert gas into the transfer module via a showerhead of the transfer module.

9. The semiconductor processing method of claim 8, wherein the transferring of the semiconductor wafer from the process chamber to the transfer module includes:
sensing pressure in the transfer module using a pressure sensor;
evacuating the transfer module using a high vacuum pump; and
transferring of the semiconductor wafer from the process chamber to the transfer module when the sensed pressure in the transfer module deceases to a wafer removal threshold pressure.

10. The semiconductor processing method of claim 1, wherein performing of the processing on the semiconductor wafer disposed in the process chamber includes:
performing ion beam etching (IBE) on the semiconductor wafer disposed in the process chamber.

11. The semiconductor processing method of claim 10, wherein:
the semiconductor wafer includes a magnetic tunnel junction (MTJ) multilayer structure; and
the performing of IBE on the semiconductor wafer disposed in the process chamber includes performing patterned etching of the MTJ multilayer structure to form MTJ mesas.

12. A semiconductor processing system comprising:
an ion beam etching (IBE) tool comprising a process chamber, a wafer holder configured to hold a semiconductor wafer, and an ion beam source arranged to direct an ion beam toward the wafer holder;
a vacuum transfer module;
a load port configured to transfer semiconductor wafers to and from the vacuum transfer module;
a transfer module connected with the IBE tool;
a passthrough connecting the transfer module and the vacuum transfer module;
a wafer transfer mechanism configured to transfer semiconductor wafers between the IBE tool and the vacuum transfer module; and
a turbomolecular pump having a first valved vacuum connection to the transfer module via which the turbomolecular pump draws vacuum in the transfer module, and a second valved vacuum connection to the passthrough via which the turbomolecular pump draws vacuum in the passthrough.

13. The semiconductor processing system of claim 12, wherein the transfer module includes a transfer module showerhead and a transfer module mass flow controller (MFC) configured to flow an inert gas into the transfer module through the transfer module showerhead.

14. The semiconductor processing system of claim 13, further comprising:
a transfer module pressure sensor connected to sense pressure in the transfer module; and
a controller configured to control the transfer module MFC based on the pressure sensed by the transfer module pressure sensor.

15. The semiconductor processing system of claim 12, wherein the passthrough further includes a passthrough showerhead and a passthrough mass flow controller (MFC) configured to flow an inert gas into the passthrough through the passthrough showerhead.

16. The semiconductor processing system of claim 15, further comprising:
a passthrough pressure sensor connected to sense pressure in the passthrough; and
a controller configured to control the passthrough MFC to maximize flow of the inert gas into the passthrough constrained by keeping the pressure sensed by the passthrough pressure sensor at or below a threshold pressure.

17. A passthrough for connecting a semiconductor processing tool with a vacuum transfer module, the passthrough comprising:
a hollow transfer tube including a first end configured to connect with the semiconductor processing tool or a transfer module thereof, a second end configured to connect with the vacuum transfer module, and a vacuum port configured to connect with a high vacuum line; and
a showerhead connected with the hollow transfer tube between the first end and the second end.

18. The passthrough of claim 17, wherein the vacuum port and the showerhead are disposed on opposite sides of the hollow transfer tube.

19. The passthrough of claim 17, wherein the hollow transfer tube further includes a second vacuum port configured to connect with a rough pumping line.

20. The passthrough of claim 17, further comprising:
a mass flow controller (MFC) operatively connected to control gas flow into the showerhead.
